(19) United States
(12) Patent Application Publication
(10) Pub. No.: US 2026/0024705 A1
(43) Pub. Date: Jan. 22, 2026

(54) MULTILAYER CERAMIC CAPACITOR AND CIRCUIT BOARD

(71) Applicant: TAIYO YUDEN CO., LTD., Tokyo (JP)

(72) Inventors: Tomoki INOUE, Tokyo (JP); Yoshinari TAKE, Tokyo (JP); Takeshi SAKASHITA, Tokyo (JP); Yuka NAITO, Tokyo (JP)

(73) Assignee: TAIYO YUDEN CO., LTD., Tokyo (JP)

(21) Appl. No.: 19/272,725

(22) Filed: Jul. 17, 2025

(30) Foreign Application Priority Data
Jul. 19, 2024 (JP) 2024-116018

(51) Int. Cl. H01G 4/30; H01G 4/10; H05K 1/18

(52) U.S. Cl. CPC H01G 4/30; H01G 4/10; H05K 1/181; H05K 2201/10015

(57) ABSTRACT

A multilayer ceramic capacitor includes: a cuboid element body having a multilayer unit alternately laminating ceramic layers and internal electrodes composed primarily of metal, a pair of covering portions arranged at both ends of the multilayer unit in the laminating direction and covering surfaces of the multilayer unit, and margin portions covering at least some of the end portions of the ceramic layers in the multilayer unit and the end portions of the internal electrodes, and connecting the pair of covering portions to each other; and a plurality of terminal electrodes electrically connected to the internal electrodes, and arranged on at least a mounting face, which is one of the faces forming the surfaces of the element body, that faces the circuit board when the multilayer ceramic capacitor mounted on the circuit board, wherein at least one of the main faces, which are the faces with the largest area among the faces forming the surfaces of the element body, has particles of a metal oxide adhered to an exposed portion that is not covered by any terminal electrodes, and the metal oxide is different from the material forming the exposed portion.

### CROSS-REFERENCE TO RELATED APPLICATIONS

This application claims the benefit of Japanese Application No. 2024-116018, filed Jul. 19, 2024, in the Japanese Patent Office. All disclosures of the document named above are incorporated herein by reference.

### BACKGROUND OF THE INVENTION

### 1. Field of the Invention

Aspects of the present invention relates to a multilayer ceramic capacitor and a circuit board.

### 2. Description of the Related Art

A wide variety of ceramic electronic components are used in high-frequency communication systems, such as those for mobile phones. There is demand for smaller and thinner ceramic electronic components, and smaller and thinner multilayer ceramic capacitors are being considered.

Patent Document 1 discloses a thin, damage-resistant multilayer ceramic capacitor, in which via-hole electrodes used to electrically connect internal electrode layers to each other and to electrically connect internal electrode layers to terminal electrodes are formed with a void inside. In the multilayer ceramic capacitor disclosed in Patent Document 1, terminal electrodes are formed on the flat surface of the element body.

### PRIOR ART DOCUMENTS

### Patent Documents

Patent Document 1: JP 2020-072263 A

### SUMMARY OF THE INVENTION

### Problem(s) to be Solved by the Invention

In the multilayer ceramic capacitor disclosed in Patent Document 1, the top and bottom surfaces opposing the element body are smooth. Therefore, when handling individualized capacitor chips in the manufacturing process, the top and bottom surfaces of the exposed element body, which are not covered by terminal electrodes, come into contact with manufacturing equipment and tools, as well as other capacitor chips, etc., and the electrostatic charge increases due to the larger contact area. This causes problems because the capacitor chips are not easy to transport due to static cling, resulting in a lower yield rate during manufacturing. An increase in electrostatic charge due to the smooth top and bottom surfaces of the element body also occurs when the cover tape is peeled from the carrier tape carrying the capacitors. Capacitor chips cling to the peeled cover tape due to the increased electrostatic charge, resulting in lower yields during mounting.

It is an object of the present invention to solve this problem by providing a multilayer ceramic capacitor with a reduced amount of static electricity generated during handling, and a circuit board on which this multilayer ceramic capacitor is mounted.

### Means for Solving the Problem

As a result of extensive research conducted to solve this problem, the present inventor discovered that the object described above could be achieved by adhering, to at least one of the exposed top or bottom faces of the element body in the multilayer ceramic capacitor, particles of a metal oxide that differs from the constituent materials of the top and bottom faces. The present invention is a product of this discovery.

A first aspect of the present invention that solves this problem is a multilayer ceramic capacitor comprising: a cuboid element body having a multilayer unit alternately laminating ceramic layers and internal electrodes composed primarily of metal, a pair of covering portions arranged at both ends of the multilayer unit in the laminating direction and covering surfaces of the multilayer unit, and margin portions covering at least some of the end portions of the ceramic layers in the multilayer unit and the end portions of the internal electrodes, and connecting the pair of covering portions to each other; and a plurality of terminal electrodes electrically connected to the internal electrodes, and arranged on at least a mounting face, which is one of the faces forming the surfaces of the element body, that faces the circuit board when the multilayer ceramic capacitor mounted on the circuit board, wherein at least one of the main faces, which are the faces with the largest area among the faces forming the surfaces of the element body, has particles of a metal oxide adhered to an exposed portion that is not covered any by any terminal electrodes, and the metal oxide is different from the material forming the exposed portion.

A second aspect of the present invention that solves this problem is a circuit board carrying the multilayer ceramic capacitor according to the first aspect of the present invention.

### Effect of the Invention

Aspects of the present invention are able to provide a multilayer ceramic capacitor in which the amount of static electricity generated during handling is suppressed, and a circuit board on which this multilayer ceramic capacitor is mounted.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a schematic diagram (perspective view) of the structure of the multilayer ceramic capacitor in a first embodiment of the present invention.

FIG. 2 is a cross-sectional view (LT cross-sectional view) from A-A in FIG. 1.

FIG. 3 is a schematic diagram showing the procedure for dividing the mapped image of the metallic element on the exposed portion of the main face of the element body into square cells with 20 μm per side.

FIG. 4 is a schematic diagram (LT cross-sectional view) showing the structure of a multilayer ceramic capacitor with particles of a metal oxide adhering only to the mounting face.

FIG. 5 is a schematic diagram (LT cross-sectional view) of the structure of the multilayer ceramic capacitor in the second embodiment of the present invention.

FIG. 6 is a schematic diagram (perspective view) of the structure of the multilayer ceramic capacitor in the third embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

The configuration and effects of the present invention will now be described, including technical ideas, with reference to the accompanying drawings. However, this description includes assumptions about the operating mechanism, and the correctness of these assumptions does not limit the scope of the present invention.

### Multilayer Ceramic Capacitor

### First Embodiment

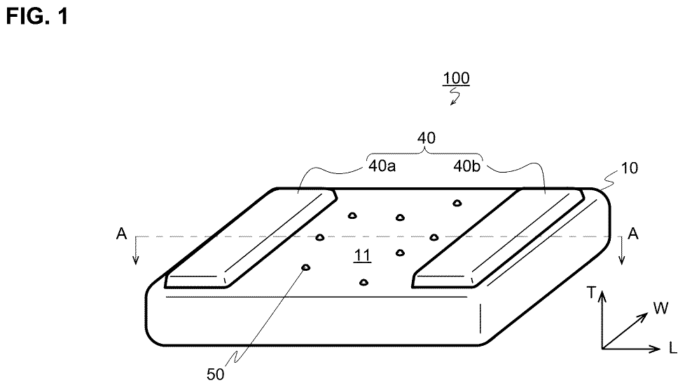

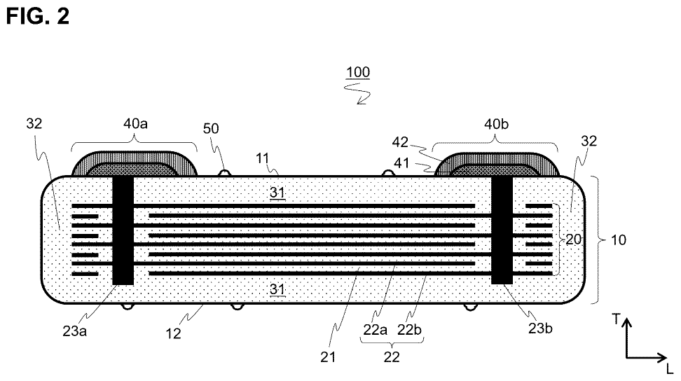

An embodiment of the multilayer ceramic capacitor in the first aspect of the present invention is shown in FIG. 1 to FIG. 2 as a first embodiment. The multilayer ceramic capacitor 100 in the first embodiment has a cuboid shape with a pair of faces each perpendicular to the three axes, namely, an L-axis in the length direction, a W-axis in the width direction, and a T-axis in the height direction, where these axes are orthogonal to each other. The cuboid is not limited to a cuboid as defined mathematically, but includes any shape that is recognizable as a cuboid after observing its overall shape. Therefore, those with edges and corners that are slightly rounded, edges that are slightly curved, and surfaces that are curved surfaces with a small curvature also fall under the category of cuboid in the present disclosure. The length (L), width (W), and height (T) dimensions of the ceramic capacitor 100 can each be set independently to any value.

Examples of dimensions for the multilayer ceramic capacitor 100 are an L-direction dimension of 200 μm or more and 2000 μm or less, a W-direction dimension of 100 μm or more and 2000 μm or less, a T-direction dimension of 30 μm or more and 220 μm or less, and a W/L ratio, or the ratio of the W-direction dimension to the L-direction dimension, of 0.3 or more and 1.0 or less. Each of these dimensions is preferably an L-direction dimension of 400 μm or more and 1200 μm or less, a W-direction dimension of 400 μm or more and 1200 μm or less, a T-direction dimension of 40 μm or more and 150 μm or less, and a W/L ratio, which is the ratio of the W-direction dimension to the L-direction dimension, of 0.4 or more and 1.0 or less. The T-direction dimension is preferably 100 μm or less, as this is less likely to be constrained by the design of the circuit board on which it is mounted.

As schematically shown in the cross-sectional view in FIG. 2, the multilayer ceramic capacitor 100 in the first embodiment comprises an element body 10 having a multilayer unit 20 obtained by alternately laminating in the T direction ceramic layers 21 and internal electrodes 22 composed primarily of metal, a pair of covering portions 31 arranged on both ends of the multilayer unit 20 in the laminating direction and covering surfaces of the multilayer unit 20, and a margin portion 32 connecting the pair of covering portions 31 while covering at least some of the end portions of the ceramic layers 21 and the end portions of the internal electrodes 22 in the multilayer unit 20. The internal electrodes 22 include internal electrodes 22a of one polarity electrically connected to each other, and an internal electrode 22b of a different polarity from the internal electrode 22a electrically connected to each other.

The method used to electrically connect the internal electrodes 22a to each other and the internal electrodes 22b to each other is not particularly limited. FIG. 2 shows a configuration in which via conductors 23 (23a, 23b) are arranged inside the element body 10 in the laminating direction of the multilayer unit 20, passing through the ceramic layers 21 and having at least one end reaching the surface of a covering portion 31 as described later. However, as shown in the second embodiment described below, the internal electrodes may be extended to the end faces of the element body 10 and be connected via external conductors. Note that the multilayer ceramic capacitor 100 shown in FIG. 2 has two via conductors 23, but the number of via conductors in the multilayer ceramic capacitor in the first aspect of the present invention is not limited to this.

The covering portions 31 are disposed on the surfaces of the element body 10 perpendicular to the T direction of multilayer unit 20, and the margin portions 32 are disposed on the surfaces perpendicular to the W direction and perpendicular to the L direction of the multilayer unit 20. Note that, as described in the second embodiment below, when the internal electrodes are drawn out to the end faces of the element body 10, margin portions are not provided on the end faces (draw-out faces) where the internal electrodes are drawn out.

The multilayer ceramic capacitor 100 in the first embodiment comprises a plurality of terminal electrodes 40 (40a, 40b) that are electrically connected to the internal electrodes 22 (22a, 22b) and are arranged at least on the mounting face 11, which is one of the faces forming the surfaces of the element body 10, facing the circuit board when the capacitor is mounted on the circuit board. The method used to electrically connect the terminal electrodes 40 (40a, 440b) and internal electrodes 22 (22a, 22b) is not particularly limited. FIG. 2 shows a configuration in which the electrodes are connected by way of via conductors 23 (23a, 23b), but as described in the second embodiment below, they may also be connected by way of external conductors. Note that the multilayer ceramic capacitor 100 in FIG. 2 has two terminal electrodes 40, but the number of terminal electrodes in the multilayer ceramic capacitor in the first aspect of the present invention is not limited to this.

In the multilayer ceramic capacitor 100 of the first embodiment, an exposed portion on at least one of the main faces that has the largest area forming the surface of the element body 10, that is, portions not covered by terminal electrodes 40 (40a, 40b) or the external conductors described below, have particles 50 of a metal oxide different from the material forming the exposed portions adhering to it. Note that the multilayer ceramic capacitor 100 shown in FIG. 2 has two main faces on opposite sides of the element body 10, namely, a mounting face 11 and an opposite face 12 on the opposite side, and particles 50 of metal oxide are adhering to both main faces. However, the multilayer ceramic capacitor of the first embodiment of the present invention may have a face other than the mounting face and the opposite face serving as a main faces, or particles of a metal oxide may be adhered to only one main face.

The thickness of the element body 10, obtained by subtracting the thickness of the terminal electrodes 40 (40a, 40b) from the T-direction dimension of the multilayer ceramic capacitor 100, is, for example, 20 μm or more and 200 μm or less, and preferably 30 μm or more and 180 μm or less.

Each component constituting the multilayer ceramic capacitor 100 in the first embodiment will now be described in detail.

### (Ceramic Layers)

Ceramic layers 21 are formed of ceramic. The composition of the ceramic is not particularly limited as long as it forms dense ceramic layers 21 when simultaneously fired with the internal electrodes 22 described below, and may be selected based on the characteristics required of the multilayer ceramic capacitor. Examples of ceramic compositions include those composed primarily of barium titanate (BaTiO₃), strontium titanate (SrTiO₃), and Ba_{1-x-y}CaₓSr_{y}Ti_{1-z}Zr₂O₃, which has a perovskite structure. The ceramic may contain additive elements along with the main components mentioned above. Examples of additive elements include at least one selected from Mo, Nb, Ta, W, Mg, Mn, V, and Cr, rare earth elements (Y, Sm, Eu, Gd, Tb, Dy, Ho, Er, Tm, and Yb), and Co, Ni, Li, B, Na, K, and Si. Additive elements may be present as individual elements or in the form of compounds such as oxides, nitrides, and carbides. In addition, the additive elements may be present in a solid solution state along with the primary components, or may form a different phase with the elements constituting the primary components or other additive elements.

### (Internal Electrodes)

The internal electrodes 22 (22a, 22b) are primarily composed of metal. The type of metal is not particularly limited, and examples include nickel (Ni), copper (Cu), palladium (Pd), platinum (Pt), silver (Ag), and gold (Au), as well as alloys of these metals. Among these metals, those containing nickel (Ni) as the primary constituent element are preferable because of their high heat resistance, which allows the firing temperature to be increased during firing together with the ceramic layers 21 to form dense ceramic layers 21, and because they are relatively inexpensive. In the present specification, “primary constituent element” refers to the element with the highest content expressed as atomic percentage (atom %).

The internal electrodes 22 (22a, 22b) may contain, in addition to metal, ceramic particles having the same composition as the ceramic constituting the ceramic layers 21, or glass components.

### (Covering Portions and Margin Portions)

The covering portions 31 and the margin portions 32 both have a function of protecting the ceramic layers 21 and the internal electrodes 22. Materials for the covering portions 31 and the margin portions 32 are not limited as long as they have high electrical insulation properties and low permeability to moisture and other deteriorating factors. In order to provide uniform shrinkage during firing and relieve internal stress in the multilayer ceramic capacitor 100, the primary component of the covering portions 31 and the margin portions 32 is preferably the same as the ceramic used to form the ceramic layers 21.

### (Via Conductors)

The via conductors 23 (23a, 23b) are composed primarily of metal, similar to the internal electrodes 22 (22a, 22b). The metals that can be used are the same metals as those used in the internal electrodes 22 (22a, 22b) described above. The composition of the via conductors may be different from that of the internal electrodes 22 (22a, 22b), but is preferably the same as that of the internal electrodes 22 (22a, 22b). When the via conductors 23 (23a, 23b) and the internal electrodes 22 (22a, 22b) have the same composition, the amount of shrinkage caused by firing is uniform during production of the multilayer ceramic capacitor 100, thereby suppressing deformation. The resistivity of the conductive paths in the multilayer ceramic capacitor 100 are also uniform, thereby suppressing localized heating during use.

The diameter of the via conductors 23 (23a, 23b) is not particularly limited, but in order to ensure the capacitance of the multilayer ceramic capacitor 100 while reducing electrical resistance and suppressing heat generation during circuit operation, the diameter is preferably 5 μm or more and 100 μm or less, and more preferably 10 μm or more and 50 μm or less.

### (Terminal Electrodes)

The material of the terminal electrodes 40 (40a, 40b) is not limited as long as it is a conductive material. Examples of materials include metals such as nickel (Ni), copper (Cu), tin (Sn), palladium (Pd), platinum (Pt), silver (Ag), and gold (Au), alloys containing any of these as the primary constituent element, and conductive resins.

The terminal electrodes 40 (40a, 40b) may include base conductors 41 in contact with the element body 10 and plated conductors 42 formed on the surface of the base conductors 41. Terminal electrodes 40 (40a, 40b) with this structure improve the bonding strength to the element body 10 by the base conductors 41, while improving solder wettability during circuit board mounting by the plated conductors 42.

An example of a material for the base conductors 41 is Ni. The thickness of the base conductors 41 is, for example, 0.1 μm or more and 10 μm or less, and preferably 0.5 μm or more and 5 μm or less.

The plated conductors 42 may be formed with a single layer or multiple layers. When the plated conductors 42 have multiple layers, they preferably have two to four layers. The material and structure of plated conductors 42 can be a structure formed in the order Cu, Ni, and Sn. The thickness of the plated conductors 42 is, for example, 1 μm or more and 20 μm or less, and preferably 3 μm or more and 10 μm or less.

The area of the terminal electrodes 40 (40a, 40b), that is, the area of the terminal electrodes 40 (40a, 40b) as viewed from the direction perpendicular to the mounting face 11 of the multilayer ceramic capacitor 100, is not particularly limited, but should be large enough to facilitate mounting of the capacitor on a circuit board, but small enough to prevent short circuits between electrodes with different polarities. Preferably, the ratio of the total area of the terminal electrodes 40 to the area of the mounting face 11 is 0.2 or more and 0.9 or less, and more preferably, 0.3 or more and 0.8 or less.

### (Particles of Metal Oxide)

The particles 50 of metal oxide are adhered to the exposed portions of a main face of the element body 10. This reduces the contact area with other members and elements by forming protruding portions on the exposed portion of the main face, which reduces the amount of static electricity generated. Here, “adhere” means the particles 50 of metal oxide wet the exposed portion of the main face or bite into the interior of the element body 10 from the exposed portion as for condition, or refers to the strength that remains on the main face after the release tape attached to the exposed portion of the main face has been peeled off as for adhesion strength, which differs from mere contact. By adhering particles 50 of metal oxide to an exposed portion of a main face of the element body 10, detachment of the particles 50 of metal oxide is suppressed during handling of the multilayer ceramic capacitor 100 and during use of the circuit board carrying the capacitor. This maintains the electrostatic suppression effect over a long period of time, and prevents circuit board failures caused by detached particles 50 of metal oxide.

The particles 50 of metal oxide are formed of a different metal oxide than the material that forms the face to which they adhere, that is, an exposed portion not covered by terminal electrodes 40 (40a, 40b) or an external conductor, on at least one of the main faces that has the largest area of each face forming the surfaces of the element body 10. This creates an area with a different surface potential on the exposed portion of the main face and suppresses the amount of static electricity generated. Here, a metal oxide that is different from the material forming the exposed portion of the main face is meant to include oxides of metallic elements different from the metallic elements contained in the exposed portion, of course, but also composite oxides that contain metallic elements included in the exposed portion but also other metallic elements that are not included in the exposed portion, oxides that do not include some of the plurality of metallic elements included in the exposed portion, and oxides that match the metallic elements include in the exposed portion but differ in terms of the ratio of the metallic elements included therein.

The metallic elements and number of them in the metal oxide are not limited, but when the terminal electrodes 40 (40a, 40b) have a base conductor 41 and a plating conductor 42, as described above, it is preferable that the metallic elements are the same as those in the base conductor 41. This improves the adhesion strength between the particles 50 of metal oxide and the element body 10, and has a noticeable effect of inhibiting the detachment of particles 50 of metal oxide when the multilayer ceramic capacitor 100 is handled and when a circuit board carrying the capacitor is used. The oxides of metallic elements included in a base conductor 41 commonly used in the art have high electrical insulating properties, so even if the oxide particles are adhering to an exposed portion of the element body 10, the electrical insulating properties of the multilayer ceramic capacitor surface are not easily degraded.

When the metal oxide is nickel oxide, it has the advantage of suppressing the degradation of characteristics caused by a magnetic field applied externally to the multilayer ceramic capacitor 100. This is presumably because nickel oxide is an antiferromagnet with no magnetic moment and therefore does not respond magnetically to external magnetic fields.

The area density of the particles 50 of metal oxide in an exposed portion of a main face on which the particles 50 of metal oxide are adhered is preferably between 5×10⁻⁵ particles/μm² and 500×10⁻⁴ particles/μm². When the area density is within this range, the effect of reducing the amount of static electricity becomes more pronounced. The area density is more preferably between 1×10⁻⁴ particles/μm² and 480×10⁻⁴ particles/μm², and even more preferably between 3×10⁻⁴ particles/μm² and 450×10⁻⁴ particles/μm².

When the area density is within the preferred range, the percentage of the total number of cells in which particles 50 of metal oxide are present after the exposed portion is divided into square cells with sides of 20 μm is preferably at least 20% of the total number of cells. This means the particles 50 of metal oxide are distributed over a wider area in the exposed portion, which makes the reduction of static electricity more pronounced. The percentage is preferably at least 25% and even more preferably at least 30%.

The particle diameter of the particles 50 of metal oxide is preferably 0.1 μm or more and 10 μm or less. This makes the effect of reducing the amount of static electricity more pronounced. The particle size is preferably 0.3 μm or more and 9 μm or less, and even more preferably 0.5 μm or more and 8 μm or less.

At least one of the particles 50 of metal oxide preferably has a protrusion height of 0.5 μm or more and 10 μm or less from the main face on which it adheres. When the protrusion height is 0.5 μm or more, the reduction in the amount of static electricity becomes more pronounced. From this standpoint, a protrusion height of 1 μm or more is more preferred, and a protrusion height of 1.5 μm or more is even more preferred. Meanwhile, when the protrusion height is 10 μm or less, defects related to the particles 50 of metal oxide are suppressed, which prevents circuit board failures caused by detached particles 50 of metal oxide. From this standpoint, a protrusion height of 9 μm or less is more preferred, and a protrusion height of 8 μm or less is even more preferred. From the above, a protrusion height of 1 μm or more and 9 μm or less is more preferred, and a protrusion height of 1.5 μm or more and 8 μm or less is even more preferred.

The following procedure is used to determine whether particles 50 of a metal oxide different from the material forming the exposed portion of the main face of the element body 10 are adhering to the exposed portion, and to determine the protrusion height of the particles 50 of metal oxide. First, the application and removal of release tape is repeated several times on the exposed portion of the main face of the element body 10 in the multilayer ceramic capacitor 100. This removes the fine particles that are merely contacting on the exposed portion. Next, carbon is deposited on the exposed portion to make a measurement sample. Next, the exposed carbon-deposited portion of the measurement sample is observed under a scanning electron microscope (SEM) equipped with an energy dispersive X-ray spectrometer (EDS) and reflection electron detectors. Then, the unevenness of the exposed portion is analyzed using three-dimensional measurement software, and the presence of particle-like protrusions is used to determine that the protrusions are particles adhering to the exposed portion. Next, a compositional analysis is performed on the exposed portion using EDS to obtain a mapped image of the main component elements. Next, when a contrast difference is confirmed in an adhered particle portion in at least one of the acquired mapped images of each metal element, and it is confirmed from each mapped image that the adhered particle portion contains metal elements and oxygen, it is determined that the adhered particle is a particle 50 of a metal oxide that is different from the material that forms the exposed portion. Next, in the results of the unevenness analysis of the exposed portion, the difference in height between the lowest point at the boundary between a particle 50 of metal oxide adhering to the exposed portion and the main face of the element body 10 and the highest point of the particle 50 of metal oxide is calculated, and the result is used as the protruding height of the particle 50 of metal oxide.

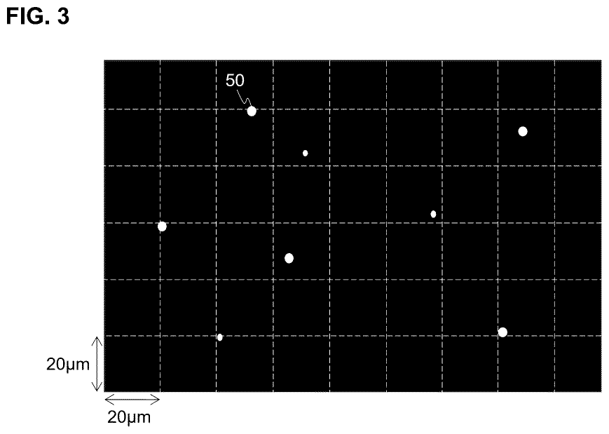

The area density of the particles 50 of metal oxide adhering to the exposed portion of the main face of the element body 10, the particle size, and the percentage of the total number of cells in which the particles 50 of metal oxide are present are determined using the following procedures. First, among the mapped images of each metal element obtained in the procedure for determining the presence or absence of adhering particles 50 of metal oxide, the one in which the particle-like contrast is most clearly present is selected, the mapped image is binarized using image analysis software, and the particle-like regions are counted. This operation may be performed by visual confirming in the mapped image whether individual particle-like regions are clearly distinguishable from each other and their number is small. The number of particle-like regions obtained is then divided by the area (μm²) of the exposed portion in the mapped image, and the value obtained is the area density of particles 50 of metal oxide adhering to the exposed portion (particles/μm²). Next, the maximum distance between two different points located on the outline of a particle-shaped region in the mapped image after binarization is measured using image analysis software, and this is used as the particle size of the particle 50 of metal oxide. Next, in an mapped image in which the particle-like regions have been counted, line segments are drawn at intervals corresponding to 20 μm from the left edge and the bottom edge as shown in FIG. 3. Next, the cells demarcated by the drawn line segments and located entirely in the exposed region are counted to determine the total number of cells. Next, the cells that are located entirely in the exposed region and that encompass particle-like regions are counted to determine the number of cells in which particles 50 of metal oxide are present. If a particle-like region is present across adjacent cells, it is assumed to be included in one of the cells and counted as being in that cell. Cells with one side less than 20 μm along at the right edge and the top edge of the mapped image, are excluded from the count with respect to any particles 50 of metal oxide that may be present in these cells. The number of cells in which particles 50 of metal oxide are present is divided by the total number of cells and multiplied by 100, which is the percentage of cells in which particles 50 of metal oxide are present.

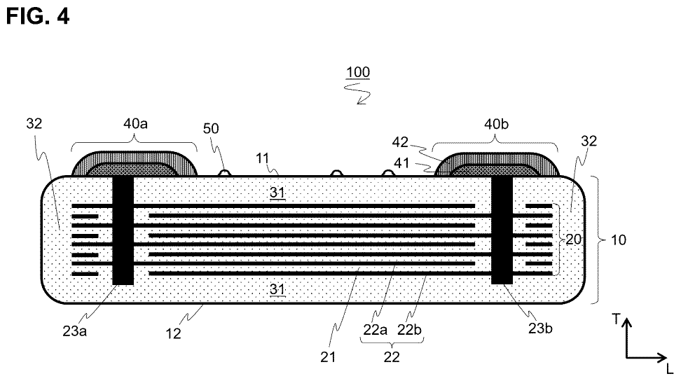

As mentioned above, the particles 50 of metal oxide may be adhered to one or both main faces of the element body 10 exposed on the surface of the multilayer ceramic capacitor 100. In the multilayer ceramic capacitor 100, when the main faces of the element body 10 form the mounting face 11 and the opposite face 12, which is the face opposite the mounting face, the distance between the mounting face 11 and the opposite face 12 is less than 100 μm, which is a low profile type with an extremely low element height, and no electrodes are placed on the opposite face 12, as shown in FIG. 4, it is preferable from the standpoint of element height that the particles 50 of metal oxide be adhered only to the mounting face 11.

### Second Embodiment

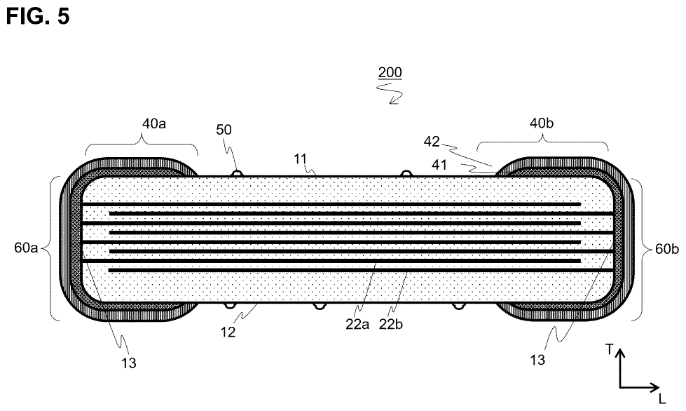

Another embodiment (second embodiment) of the multilayer ceramic capacitor in the first aspect of the present invention is one in which the internal electrodes are electrically connected to each other via external conductors. An example of a multilayer ceramic capacitor 200 in the second embodiment is shown in FIG. 5. In the multilayer ceramic capacitor 200, the internal electrodes 22 (22a, 22b) drawn out to the drawn-out faces 13 of the element body 10 are electrically connected to each other by external conductors 60 (60a, 60b), and the external conductors 60 (60a, 60b) are electrically connected to the terminal electrodes 40 (40a, 40b) arranged on the mounting face 11. Note that, while FIG. 5 shows an example in which the external conductors 60 (60a, 60b) are formed on a pair of drawn-out faces 13 opposite each other that wrap around to the opposite face 12, the external conductors may be formed on just a single lead-out face or the lead-out faces may be formed without wrapping around to the opposite face.

### Third Embodiment

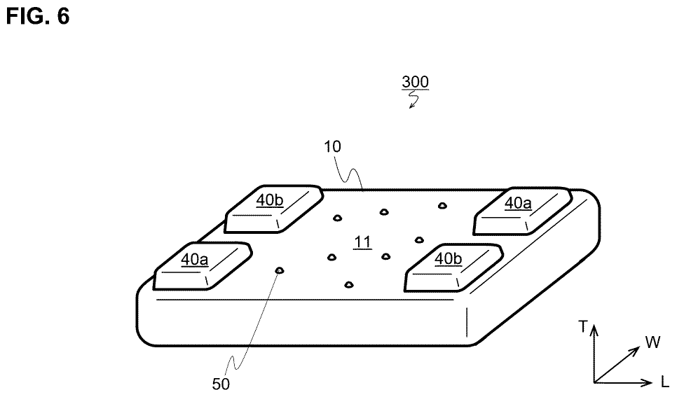

Another embodiment (third embodiment) of the multilayer ceramic capacitor in the first aspect of the present invention has four or more terminal electrodes arranged on the mounting face. An example of a multilayer ceramic capacitor 300 in the third embodiment is shown in FIG. 6. Note that while the number of terminal electrodes 40 arranged on the mounting face 11 in FIG. 6 is four, the number of terminal electrodes arranged on the mounting face is not limited to this. The multilayer ceramic capacitor 300 has the advantage of reducing resistive heating because it can suppress the amount of current flowing through the via conductors 23 (23a, 23b) electrically connected to each terminal electrode 40 (40a, 40b). Also, when the polarities of the terminal electrodes 40 (40a, 40b) that are closest to each other on the mounting face 11 are different, the directions in which the current flows through the via conductors 23 (23a, 23b) electrically connected to each terminal electrode 40 (40a, 40b) are opposite to each other between the closest via conductors 23 (23a, 23b). Therefore, the magnetic fields generated by the current cancel each other out, which has the advantage of reducing the equivalent series inductance (ESL). The ESL reducing effect is significant when the mounting face 11 of the multilayer ceramic capacitor 300 has a shape close to a square, that is, when the ratio of W to L, that is, W/L, is 0.8 or greater and 1 or less, where among the two opposite faces parallel to the laminating direction of the multilayer unit, the distance in one direction, that is, the L-direction dimension, is L μm, and the distance in the other direction, that is, the W-direction dimension, is W μm (where L≥W).

### Method for Manufacturing Multilayer Ceramic Capacitor

The multilayer ceramic capacitor in the first aspect of the present invention can be manufactured by performing the following steps.

### Preparation of Ceramic Powder (A)

First, the ceramic powder is prepared. Commercially available ceramic powder can be used when appropriate. When preparing the ceramic powder, the raw material powders containing the constituent elements may be mixed together at the specified ratios and preliminary firing (pre-firing) performed. When mixing the raw material powders together at the predetermined ratios, additives such as the additive elements listed above and sintering aids may be added. However, these additives may also be added to the powder after pre-firing.

### Preparation of Green Sheets (B)

Next, the ceramic powder is mixed with a binder and a dispersing medium to prepare a slurry, and the slurry is formed into a sheet to obtain a green sheet.

The binder can be any one that can maintain the shape of the green sheet and, during binder removal processing prior to firing, allows volatile substances to evaporate without leaving carbon or other residues. Examples of binders that can be used include polyvinyl alcohol-based, polyvinyl butyral-based, cellulose-based, urethane-based, and vinyl acetate-based binders. The amount of binder used is not particularly limited, but since it is to be removed in a subsequent step, it is preferable to use as little as possible within a range that allows the desired moldability and shape retention to be obtained and that also reduces raw material costs.

The dispersing medium can be one that does not cause agglomeration of the pre-fired powder and that enables the binder to be easily removed by volatilization, etc., after green sheet molding described below. Examples of dispersing media that can be used include water and alcohol-based solvents.

The slurry may contain components such as dispersants, plasticizers, and thickeners to adjust the properties of the slurry.

The method used to mix the mixed powder with a binder and a dispersing medium is not particularly limited as long as it prevents the introduction of impurities and ensures that each component is uniformly mixed. One example is ball mill mixing.

Methods that can be used to form the prepared slurry into a sheet to obtain a green sheet include conventional methods such as the doctor blade method and the die coating method.

### Formation of Internal Electrode Patterns (C)

Next, an internal electrode pattern containing metal is formed on the green sheet. The internal electrode pattern can be formed by printing or coating an internal electrode paste in a predetermined pattern, or by forming a metal film in a predetermined pattern by vapor deposition or sputtering deposition. The internal electrode pattern is formed with sufficient margin to ensure electrical insulation from the via conductor pattern formed later, with which it is not to make contact.

When forming an internal electrode pattern using internal electrode paste, the internal electrode paste used is obtained by mixing metal particles into a vehicle using a three-roll mill. The internal electrode paste may also contain glass frit or ceramic powder in addition to these components.

The types and amounts of binders and solvents included in the vehicle to be used are not limited, but should be selected after taking into consideration the viscosity of the internal electrode paste, ease of handling, and compatibility with the green sheet.

Printing of the internal electrode paste on the green sheet can be performed, for example, using a screen mask with a predetermined internal electrode pattern formed upon it. When printing, a space is left for the margins when used as a multilayer ceramic capacitor.

### Preparation of Green Multilayer Unit (D)

Next, a predetermined number of green sheets with internal electrode patterns formed on them are laminated, and the green sheets are bonded together by pressing to obtain a green multilayer unit. The laminating and bonding can be performed using conventional methods. For example, green sheets can be laminated by heating them while pressing them in the laminating direction, and then heat-bonding them together using a binder.

When laminating and bonding, a green sheet may be added to the end portions in the laminating direction to serve as covering portions once the multilayer ceramic capacitor is formed. In this case, the added green sheets may have the same composition as the green sheets on which the internal electrode pattern is printed, or may have a different composition. From the standpoint of ensuring uniform shrinkage during firing, the composition of the added green sheets is preferably the same or similar to that of the green sheets in which the internal electrode precursors have been arranged.

### Formation of Via Conductors (E)

When manufacturing a multilayer ceramic capacitor in the first embodiment, holes are formed in the green multilayer unit, and a conductor paste is added to fill the holes and form a via conductor pattern. Conventional methods such as drilling and laser cutting can be used to form the holes. Among these, laser cutting is preferred because it produces smooth machined surfaces. Conventional methods such as injection using a syringe or printing using a metal mask can be used to fill the holes with the conductive paste. Among these, printing using a metal mask is preferred due to its excellent filling properties for small holes. The same components as those used for the internal electrode paste described above can be used for the conductive paste, and the proportions of each component can be determined based on the filling properties for the holes.

### Formation of Terminal Electrode Pattern (F)

Next, a terminal electrode pattern is formed on at least one of the surfaces perpendicular to the laminating direction of the green multilayer unit (the mounting face). At this time, a green sheet that will become the covering portion once the multilayer ceramic capacitor is formed can be applied so that it covers the via conductor pattern on the opposite face where the terminal electrode pattern is not formed. The terminal electrode pattern can be formed by printing or coating terminal electrode paste, or by forming metal film by vapor deposition or sputtering deposition. At this time, the terminal electrode pattern may be formed using a mask with a predetermined pattern, or a paste film or metal film may be formed over the entire mounting face of the green multilayer unit and the portions other than the terminal electrode pattern removed to form a pattern. Surface milling and barrel grinding, etc. can be used to remove parts other than the terminal electrode pattern. When using terminal electrode paste to form a terminal electrode pattern, the same components as those used for the internal electrode paste described above can be used, and the proportions of each component can be determined so that a uniform pattern of a specified thickness can be obtained.

### Formation of Particles of Metal Oxides or Their Precursors (G)

Next, at least one of the main faces of the green multilayer unit is formed with particles of metal oxide or particles of a precursor that will become the metal oxide during the firing described below. Particles of a metal oxide or particles of its precursor can be formed by pressing a release sheet in which the particles are embedded against the main face of the green multilayer unit, or by printing a paste containing the particles on the main face of the green multilayer unit. When the main face of the green multilayer unit is the mounting face and the metal oxide is an oxide of the metal forming the terminal electrode pattern, particles of the metal oxide precursor can be formed during formation of the terminal electrode pattern in (F) above using a mask in which a terminal electrode pattern and a metal oxide particle pattern are formed.

### Preparation of Pre-Fired Chips (H)

Next, the green multilayer unit is divided into individual multilayer ceramic capacitor shapes through a process called “chipping” to obtain pre-fired chips. Chipping can be performed using conventional methods with a dicing saw or a laser cutting machine. After separating the green multilayer unit into individual units and forming a surface exposing the internal electrode precursors, the surface may be coated with a material to the margin portions before using the individual units as pre-fired chips.

### Removal of Binder (I)

Next, the pre-fired chips are heated to volatilize and remove the binder. The heating conditions can be set after taking into consideration the volatilization temperature and content of the binder. In one example, the temperature is held at 200° C. to 500° C. for 5 to 20 hours in a nitrogen (N₂) atmosphere.

### Firing of Pre-Fired Chips (J)

Next, the pre-fired chips with the binder removed are heated to a specified temperature and fired. When setting the firing conditions, the sinterability of the ceramic powder and the heat resistance and oxidation resistance of the metals contained in the internal electrode pattern, via conductor pattern, and terminal electrode pattern should be taken into consideration. In one example of firing conditions, the temperature is held at 1100° C. to 1400° C. for 10 minutes to 2 hours in a reducing atmosphere that is a mixture of nitrogen (N₂), hydrogen (H₂), and water vapor (H₂O). After firing, a re-oxidation treatment is optionally performed by holding the temperature at 600° C. to 1000° C. in a nitrogen (N₂) gas atmosphere or a low-oxygen atmosphere. In (G) above, when particles of the metal that is a precursor of the metal oxide are formed, they become metal oxide during this re-oxidation treatment.

### Formation of External Conductors and Terminal Electrodes (J)

When manufacturing a multilayer ceramic capacitor in the second embodiment, step (E) above is omitted, and external conductors are formed by following step (J), or steps (E) and (F) are omitted, and external conductors and terminal electrodes are formed by following step (J). The method used to form the external conductors and terminal electrodes include applying conductive paste by printing or dipping and then baking, or forming metal film by physical vapor deposition (PVD) such as vapor deposition.

The fired body obtained in this manner can be used as a multilayer ceramic capacitor as is, or a conductive layer can be formed on the surface of the terminal electrode pattern by plating to form a multilayer ceramic capacitor.

### Circuit Board

The circuit board in the second aspect of the present invention carries a multilayer ceramic capacitor in the first aspect. This circuit board does not require wider mounting spacing of elements in order to take into consideration the negative impact of static electricity generated during handling on manufacturing efficiency and yield. As a result, the size of the circuit board can be reduced, and higher performance can be realized through higher density mounting. The following technologies are also disclosed in the present specification.

### (Addendum 1)

A multilayer ceramic capacitor comprising:
a cuboid element body having
   a multilayer unit alternately laminating ceramic layers and internal electrodes composed primarily of metal,
   a pair of covering portions arranged at both ends of the multilayer unit in the laminating direction and covering surfaces of the multilayer unit, and
   margin portions covering at least some of the end portions of the ceramic layers in the multilayer unit and the end portions of the internal electrodes, and connecting the pair of covering portions to each other; and
a plurality of terminal electrodes electrically connected to the internal electrodes, and arranged on at least a mounting face, which is one of the faces forming the surfaces of the element body, that faces the circuit board when the multilayer ceramic capacitor mounted on the circuit board, wherein at least one of the main faces, which are the faces with the largest area among the faces forming the surfaces of the element body, has particles of a metal oxide adhered to an exposed portion that is not covered by any terminal electrodes, and the metal oxide is different from the material forming the exposed portion.

### (Addendum 2)

The multilayer ceramic capacitor according to (Addendum 1), wherein the metal oxide is nickel oxide.

### (Addendum 3)

The multilayer ceramic capacitor according to (Addendum 1) or (Addendum 2), wherein the area density of the particles of the metal oxide in the exposed portion on which the particles of metal oxide are adhering is 5×10⁻⁵ particles/μm² or more and 500×10⁻⁴ particles/μm² or less.

### (Addendum 4)

The multilayer ceramic capacitor according to (Addendum 3), wherein when the exposed portion on which the particles of metal oxide are adhering is divided into square cells with a side length of 20 μm, the percentage of cells containing the particles of metal oxide out of the total number of cells is 20% or more.

### (Addendum 5)

The multilayer ceramic capacitor according to any of (Addendum 1) to (Addendum 4), wherein the particle size of the metal oxide particles is 0.1 μm or more and 10 μm or less.

### (Addendum 6)

The multilayer ceramic capacitor according to any of (Addendum 1) to (Addendum 5), wherein at least one of the particles of the metal oxide has a protruding height of 0.5 μm or more and 10 μm or less from the main face.

### (Addendum 7)

The multilayer ceramic capacitor according to any of (Addendum 1) to (Addendum 6), wherein the terminal electrode includes a base conductor in contact with the element body and a plated conductor formed on the surface of the base conductor, and the metallic element contained in the particles of the metal oxide is the same as the metallic element contained in the base conductor.

### (Addendum 8)

The multilayer ceramic capacitor according to any of (Addendum 1) to (Addendum 7), wherein
the main face is the mounting face and an opposite face opposite to the mounting face, the distance between the mounting face and the opposite face is 100 μm or less,
the opposite face does not have any electrodes, and
the metal oxide particles adhere only to the mounting face.

### (Addendum 9)

The multilayer ceramic capacitor according to any of (Addendum 1) to (Addendum 8), wherein the number of terminal electrodes is four or more.

### (Addendum 10)

The multilayer ceramic capacitor according to (Addendum 9), wherein the polarity of each terminal electrode is different from that of the other terminal electrodes closest thereto on the mounting face.

### (Addendum 11)

A circuit board carrying the multilayer ceramic capacitor according to any one of (Addendum 1) to (Addendum 10).

### INDUSTRIAL APPLICABILITY

Aspects of the present invention is able to provide a multilayer ceramic capacitor in which the amount of static electricity generated during handling is suppressed. Because this multilayer ceramic capacitor is able to improve alignment accuracy during mounting on circuit boards, high yield rates can be realized. Also, because the adverse effects of static electricity generated during handling of the multilayer ceramic capacitor on manufacturing efficiency and yields are minimal, the need to increase the mounting spacing of elements to account for these effects can be eliminated. As a result, the circuit board of the present invention can be reduced in size and its performance can be improved through higher density mounting.

Although a few embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A multilayer ceramic capacitor comprising:
a cuboid element body having
a multilayer unit alternately laminating ceramic layers and internal electrodes composed primarily of metal,
a pair of covering portions arranged at both ends of the multilayer unit in the laminating direction and covering surfaces of the multilayer unit, and
margin portions covering at least some of the end portions of the ceramic layers in the multilayer unit and the end portions of the internal electrodes, and connecting the pair of covering portions to each other; and
a plurality of terminal electrodes electrically connected to the internal electrodes, and arranged on at least a mounting face, which is one of the faces forming the surfaces of the element body, that faces the circuit board when the multilayer ceramic capacitor mounted on the circuit board, wherein
at least one of the main faces, which are the faces with the largest area among the faces forming the surfaces of the element body, has particles of a metal oxide adhered to an exposed portion that is not covered by any terminal electrodes, and
the metal oxide is different from the material forming the exposed portion.

2. The multilayer ceramic capacitor according to claim 1, wherein the metal oxide is nickel oxide.

3. The multilayer ceramic capacitor according to claim 1, wherein the area density of the particles of the metal oxide in the exposed portion on which the particles of metal oxide are adhering is 5×10⁻⁵ particles/μm² or more and 500×10⁻⁴ particles/μm² or less.

4. The multilayer ceramic capacitor according to claim 2, wherein when the exposed portion on which the particles of metal oxide are adhering is divided into square cells with a side length of 20 μm, the percentage of cells containing the particles of metal oxide out of the total number of cells is 20% or more.

5. The multilayer ceramic capacitor according to claim 1, wherein the particle size of the metal oxide particles is 0.1 μm or more and 10 μm or less.

6. The multilayer ceramic capacitor according to claim 1, wherein at least one of the particles of the metal oxide has a protruding height of 0.5 μm or more and 10 μm or less from the main face.

7. The multilayer ceramic capacitor according to claim 1, wherein the terminal electrode includes a base conductor in contact with the element body and a plated conductor formed on the surface of the base conductor, and the metallic element contained in the particles of the metal oxide is the same as the metallic element contained in the base conductor.

8. The multilayer ceramic capacitor according to claim 1, wherein
the main face is the mounting face and an opposite face opposite to the mounting face,
the distance between the mounting face and the opposite face is 100 μm or less,
the opposite face does not have any electrodes, and
the metal oxide particles adhere only to the mounting face.

9. The multilayer ceramic capacitor according to claim 1, wherein the number of terminal electrodes is four or more.

10. The multilayer ceramic capacitor according to claim 9, wherein the polarity of each terminal electrode is different from that of the other terminal electrodes closest thereto on the mounting face.

11. A circuit board carrying the multilayer ceramic capacitor according to claim 1.
